(19) United States
(12) Patent Application Publication
(10) Pub. No.: US 2018/0226281 A1
(43) Pub. Date: Aug. 9, 2018

(54) PICKUP APPARATUS

(71) Applicant: Kabushiki Kaisha Toshiba, Minato-ku (JP)

(72) Inventors: Takahiro Sogou, Yokohama (JP); Kohei Hiyama, Yokohama (JP)

(73) Assignee: Kabushiki Kaisha Toshiba, Minato-ku (JP)

(21) Appl. No.: 15/888,497

(22) Filed: Feb. 5, 2018

(30) Foreign Application Priority Data
Feb. 6, 2017 (JP) 2017-019409

(51) Int. Cl. H01L 21/67; H01L 21/683

(52) U.S. Cl. CPC H01L 21/67132; H01L 21/6836; H01L 21/6838

(57) ABSTRACT

According to one embodiment, a pickup apparatus picks up one of a plurality of semiconductor chips from a sheet. The plurality of semiconductor chips is adhered to an upper surface of the sheet. The pickup apparatus includes a supporter, a presser, a suction-holder, and a lifter. The supporter is configured to support another of the semiconductor chips from below. The other semiconductor chip is positioned adjacent to the one semiconductor chip. The presser is configured to press the other semiconductor chip from above. The other semiconductor chip is clamped between the presser and the supporter. The suction-holder is configured to be movable upward with respect to the presser. The suction-holder holds the one semiconductor chip from above. The lifter is configured to lift the one semiconductor chip from below. The lifter urges the one semiconductor chip to peel from the sheet.

### CROSS-REFERENCE TO RELATED APPLICATIONS

This application is based upon and claims the benefit of priority from Japanese Patent Application No. 2017-019409, filed on Feb. 6, 2017; the entire contents of which are incorporated herein by reference.

### FIELD

Embodiments described herein relate generally to a pickup apparatus.

### BACKGROUND

There is a pickup apparatus that picks up semiconductor chips adhered on a sheet while causing the semiconductor chips to peel from the sheet. There is a trend in recent years to reduce the thickness of semiconductor chips; and damage of the semiconductor chips occurs easily when picking up the semiconductor chips. Therefore, it is desirable to develop technology that can reduce the likelihood of the damage of the semiconductor chips occurring during pickup in a pickup apparatus.

### BRIEF DESCRIPTION OF THE DRAWINGS

FIG. 1 is a perspective view illustrating a pickup apparatus according to the embodiment;

FIG. 2 is a cross-sectional view illustrating a portion of the pickup apparatus according to the embodiment;

FIG. 3A to FIG. 3D are cross-sectional views illustrating the pickup method of the pickup apparatus according to the embodiment;

FIGS. 4A to 4D are cross-sectional views illustrating a portion of a pickup apparatus according to a reference example;

FIG. 5A to FIG. 5C are cross-sectional views illustrating a portion of a pickup apparatus according to a first modification of the embodiment; and

FIG. 6A to FIG. 6C are plan views illustrating a portion of a pickup apparatus according to a second modification of the embodiment.

### DETAILED DESCRIPTION

According to one embodiment, a pickup apparatus picks up one of a plurality of semiconductor chips from a sheet. The plurality of semiconductor chips is adhered to an upper surface of the sheet. The pickup apparatus includes a supporter, a presser, a suction-holder, and a lifter. The supporter is configured to support another of the semiconductor chips from below. The other semiconductor chip is positioned adjacent to the one semiconductor chip. The presser is configured to press the other semiconductor chip from above. The other semiconductor chip is clamped between the presser and the supporter. The suction-holder is configured to be movable upward with respect to the presser. The suction-holder holds the one semiconductor chip from above. The lifter is configured to lift the one semiconductor chip from below. The lifter urges the one semiconductor chip to peel from the sheet.

Embodiments of the invention will now be described with reference to the drawings.

The drawings are schematic or conceptual; and the relationships between the thicknesses and widths of portions, the proportions of sizes between portions, etc., are not necessarily the same as the actual values thereof. There are also cases where the dimensions and/or the proportions are illustrated differently between the drawings, even in the case where the same portion is illustrated.

In this specification and each drawing, components similar to those described above are marked with the same reference numerals; and a detailed description is omitted as appropriate.

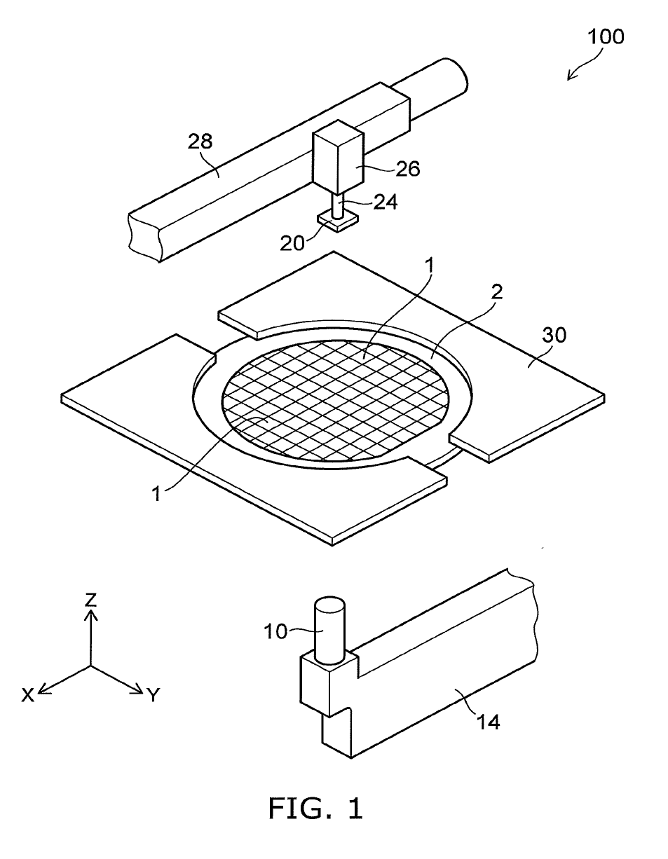

FIG. 1 is a perspective view illustrating a pickup apparatus 100 according to the embodiment.

A sheet 2 to which multiple semiconductor chips 1 are adhered is disposed in the pickup apparatus 100. The pickup apparatus 100 picks up one of the semiconductor chips 1 while causing the one semiconductor chip 1 to peel from the sheet 2.

As illustrated in FIG. 1, the pickup apparatus 100 includes a peeling apparatus 10, a peeling apparatus controller 14, a pickup head 20, an arm 24, a head controller 26, a head movement mechanism 28, and a sheet-holding table 30.

The sheet-holding table 30 holds the sheet 2 to which the multiple semiconductor chips 1 are adhered. The peeling apparatus 10 is disposed below the sheet-holding table 30. The peeling apparatus 10 urges the semiconductor chips 1 to peel from the sheet 2 when the peeling apparatus 10 picks up the semiconductor chips 1. Thereby, the semiconductor chips 1 are in a state of being able to be picked up by the pickup head 20. The peeling apparatus controller 14 moves the peeling apparatus 10 in an X-axis direction or a Y-axis direction illustrated in FIG. 1 with respect to the sheet-holding table 30, and lifts the peeling apparatus 10 toward the sheet 2.

The pickup head 20 is disposed above the sheet-holding table 30. The pickup head 20 is provided at the tip of the arm 24. The arm 24 is supported by the head controller 26. The pickup head 20 moves in the vertical direction due to the arm 24 being extended and retracted by the head controller 26. The head controller 26 is held by the head movement mechanism 28. The pickup head 20 is configured to be movable in the X-axis direction or the Y-axis direction.

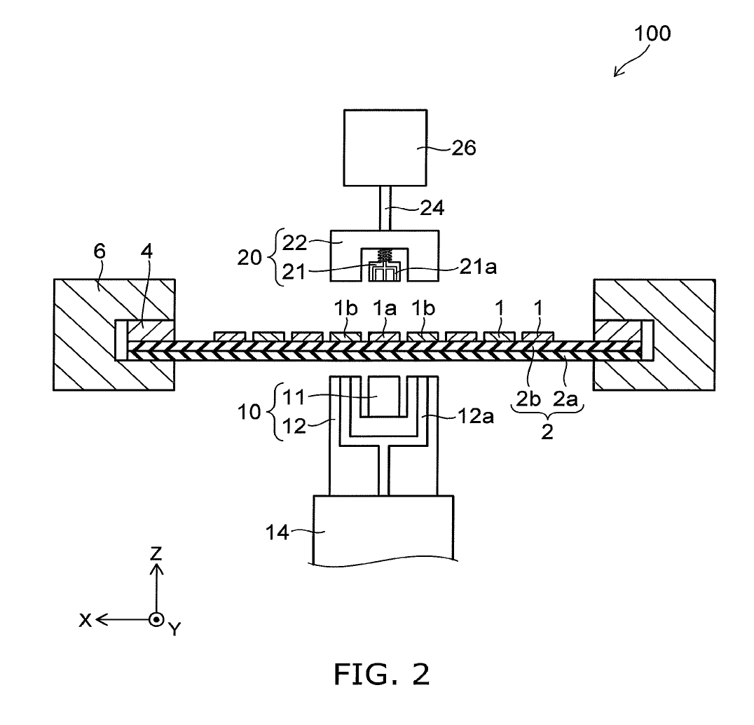

A specific structure of the pickup apparatus according to the embodiment will now be described with reference to FIG. 2.

FIG. 2 is a cross-sectional view illustrating a portion of the pickup apparatus according to the embodiment.

The peeling apparatus 10 includes a lifter 11, and a supporter 12 provided around the lifter 11. After the peeling apparatus controller 14 moves the peeling apparatus 10 below the semiconductor chips 1, the peeling apparatus controller 14 moves the peeling apparatus 10 upward. Thereby, the lifter 11 contacts, via the sheet 2, the lower surface of a semiconductor chip 1a which is the pickup object. The supporter 12 contacts, via the sheet 2, the lower surface of a semiconductor chip 1b adjacent to the pickup object.

Further, the lifter 11 is configured to be movable upward with respect to the supporter 12. The semiconductor chip 1a which is the pickup object is lifted by the lifter 11 moving further upward with respect to the supporter 12 in a state in which the lifter 11 and the supporter 12 support the semiconductor chips 1 from below. The surface area of the upper surface of the lifter 11 is less than the surface area of the semiconductor chip 1. Therefore, the lower surface outer perimeter of the lifted semiconductor chip 1a is peeled from the sheet 2.

As illustrated in FIG. 2, a suction aperture 12a may be provided in the supporter 12. The sheet 2 is suctioned via the suction aperture 12a when the semiconductor chip 1b is supported from below by the supporter 12. Thereby, the positional shift of the semiconductor chip 1b in the subsequent process can be suppressed.

The pickup head 20 includes a suction-holder 21, and a presser 22 provided around the suction-holder 21. After the head movement mechanism 28 moves the pickup head 20 (the head controller 26) above the semiconductor chips 1, the head controller 26 extends the arm 24 and moves the pickup head 20 downward. Thereby, the suction-holder 21 contacts the upper surface of the semiconductor chip 1a which is the pickup object. The presser 22 contacts the upper surface of the semiconductor chip 1b adjacent to the pickup object.

A suction aperture 21a is provided in the suction-holder 21. The upper surface of the semiconductor chip 1a is suctioned via the suction aperture 21a. Thereby, the semiconductor chip 1a is held by suction to the suction-holder 21. After the presser 22 contacts the upper surface of the semiconductor chip 1b, the presser 22 presses the upper surface of the semiconductor chip 1b from above. Thereby, the semiconductor chip 1b is clamped in the vertical direction between the supporter 12 and the presser 22. The suction-holder 21 is configured to be able to move upward relative to the presser 22 when the semiconductor chip 1a is lifted by the lifter 11 in this state.

The sheet 2 includes, for example, a base material 2a, and an adhesive layer 2b provided on the base material 2a. The semiconductor chips 1 are adhered to the upper surface of the adhesive layer 2b. A die bonding adhesive layer (a die attach material), etc., may be further provided between the adhesive layer 2b and each of the semiconductor chips. A ring 4 that is rigid is disposed at the outer perimeter of the sheet 2. The ring 4 is held by the sheet-holding table 30 illustrated in FIG. 1 with a ring holder 6 interposed.

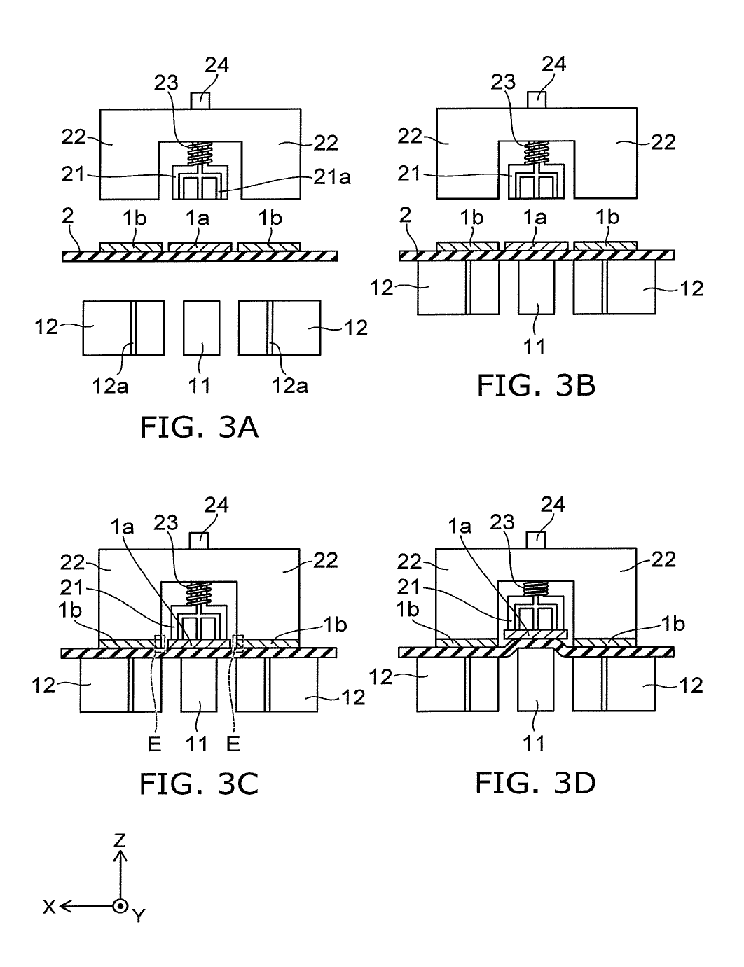

A pickup method of the semiconductor chip of the pickup apparatus 100 according to the embodiment will now be described with reference to FIG. 3A to FIG. 3D.

FIG. 3A to FIG. 3D are cross-sectional views illustrating the pickup method of the pickup apparatus 100 according to the embodiment.

As illustrated in FIG. 3A, the sheet 2 is held by the sheet-holding table 30. The multiple semiconductor chips 1 are disposed between the peeling apparatus 10 and the pickup head 20.

The peeling apparatus 10 moves upward as illustrated in FIG. 3B. Thereby, the lifter 11 and the supporter 12 contact the lower surfaces of the semiconductor chips 1a and 1b via the sheet 2; and these semiconductor chips are supported from below.

The pickup head 20 is moved downward as illustrated in FIG. 3C. Thereby, the suction-holder 21 and the presser 22 contact the upper surfaces of the semiconductor chips 1a and 1b. At this time, the semiconductor chip 1b is pressed from above by the presser 22. The semiconductor chip 1b is clamped and fixed between the supporter 12 and the presser 22. Continuing, the upper surface of the semiconductor chip 1a is held by suction by the suction-holder 21.

As illustrated in FIG. 3D, the lifter 11 is moved to be higher than the supporter 12 and lifts the semiconductor chip 1a from below. At this time, the semiconductor chip 1b that is adjacent to the semiconductor chip 1a is clamped by the supporter 12 and the presser 22. Therefore, only the semiconductor chip 1a is lifted upward; and the outer perimeter of the lower surface of the semiconductor chip 1a peels from the sheet 2.

In the example illustrated in FIG. 3A to FIG. 3D, the suction-holder 21 is linked to the presser 22 and the arm 24 via an elastic member 23. More specifically, the suction-holder 21 is slidable in the vertical direction with respect to the presser 22 and the arm 24; and the elastic member 23 is provided between the presser 22 and the arm 24. Therefore, when the semiconductor chip 1a is lifted by the lifter 11, the suction-holder 21 moves upward with respect to the presser 22 and the arm 24 while the elastic member 23 is compressed.

The pickup head 20 is moved upward in the state in which the semiconductor chip 1a is lifted and the upper surface of the semiconductor chip 1a is held by suction. Thereby, the semiconductor chip 1a which is the pickup object is peeled completely from the sheet 2; and the pickup of the semiconductor chip 1a is completed.

It is favorable for the pickup apparatus 100 to include the following configuration.

As illustrated in FIG. 3A to FIG. 3D, the length in the X-direction of the lifter 11 is shorter than the length in the X-direction of the suction-holder 21. The length in the X-direction of the suction-holder 21 is shorter than the length in the X-direction of the semiconductor chip 1a. The gap in the X-direction between the suction-holder 21 and the presser 22 is shorter than the gap in the X-direction between the lifter 11 and the supporter 12.

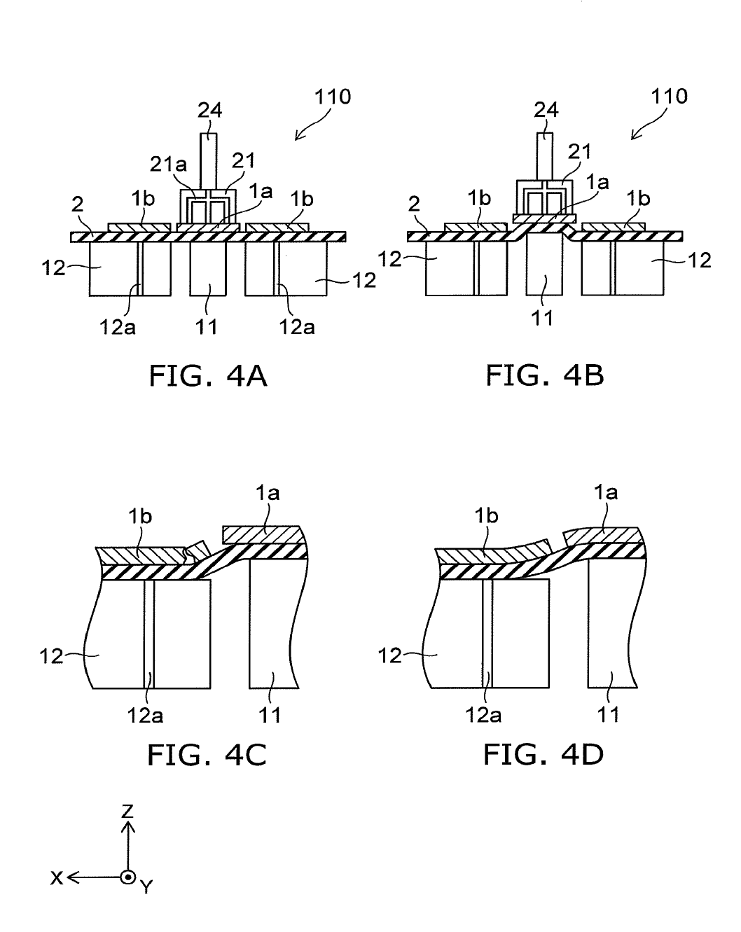

Operations and effects according to the embodiment will now be described with reference to FIGS. 4A to 4D.

FIGS. 4A to 4D are cross-sectional views illustrating a portion of a pickup apparatus 110 according to a reference example.

The pickup apparatus 110 according to the reference example differs from the pickup apparatus 100 according to the embodiment in that the presser 22 is not included.

In the pickup apparatus 110, the suction aperture 12a is provided in the supporter 12 as illustrated in FIG. 4A. The semiconductor chip 1b that is adjacent to the pickup object is fixed by holding the lower surface of the sheet 2 via the suction aperture 12a. As illustrated in FIG. 4A and FIG. 4B, when the semiconductor chip 1a which is the pickup object is held by suction by the suction-holder 21, the semiconductor chip 1a is lifted by the lifter 11 and urged to peel from the sheet 2.

In the case of the pickup apparatus 110 according to the reference example, when the semiconductor chip 1a is lifted, the sheet 2 at the semiconductor chip 1b lower portion deforms as illustrated in FIG. 4C. Thereby, there is a possibility that the semiconductor chip 1b may be damaged due to a load applied to the semiconductor chip 1b. Or, due to the deformation of the sheet 2 at the semiconductor chip 1b lower portion, the sheet 2 at the outer perimeter lower surface of the semiconductor chip 1a is not pulled sufficiently downward; and there is a possibility that the sheet 2 may not peel from the lower surface of the semiconductor chip 1a as illustrated in FIG. 4D.

To solve these problems, there exists technology to dispose the supporter 12 below the semiconductor chip 1a outer perimeter and suction the sheet 2 at the semiconductor chip 1a lower surface more directly. However, the appropriate overlap amount between the supporter 12 and the semiconductor chip 1a is different according to the material properties of the sheet 2, the strength of the semiconductor chips 1, etc. Additionally, in the case where the overlap amount is inappropriate, damage of the semiconductor chips 1 undesirably occurs more easily.

The pickup apparatus 100 according to the embodiment includes the presser 22 that presses, from above, the semiconductor chip 1b adjacent to the pickup object. During pickup, the semiconductor chip 1b is pressed from above by the presser 22; and the semiconductor chip 1b is clamped between the supporter 12 and the presser 22. The sheet 2 also is clamped and fixed between the semiconductor chip 1b and the supporter 12.

Therefore, when the semiconductor chip 1a is lifted by the lifter 11, the deformation of the sheet 2 between the semiconductor chip 1b and the supporter 12 can be suppressed. As a result, the likelihood of the semiconductor chip 1b being damaged or the sheet 2 insufficiently peeling from the outer perimeter lower surface of the semiconductor chip 1a can be reduced.

In the pickup apparatus 100 as illustrated in FIGS. 3A to 3D, the suction-holder 21 is linked to the presser 22 and the arm 24 via the elastic member 23. According to such a configuration, when the semiconductor chip 1a is lifted by the lifter 11, the suction-holder 21 can be moved upward with respect to the presser 22 in a simpler structure.

It is desirable for the presser 22 to be configured to press an end portion E of the semiconductor chip 1b on the semiconductor chip 1a side as illustrated in FIG. 3C when pressing the semiconductor chip 1b. When the semiconductor chip 1a is lifted by the lifter 11, a force is applied to the semiconductor chip 1b according to the deformation of the sheet 2 between the semiconductor chips 1a and 1b. When only the center of the semiconductor chip 1b is pressed by the presser 22, there is a possibility that a large force may be applied to the end portion E of the semiconductor chip 1b; and the semiconductor chip 1b may break. Because the presser 22 presses the end portion E of the semiconductor chip 1b, the likelihood of damage to the semiconductor chips 1 can be reduced further.

### First Modification

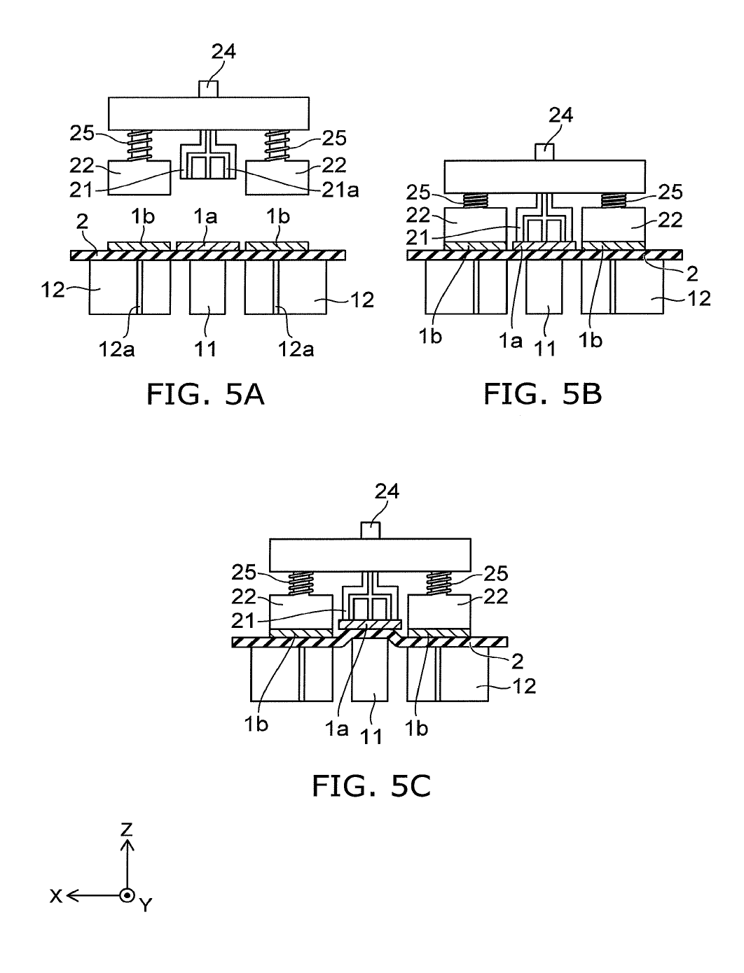

FIG. 5A to FIG. 5C are cross-sectional views illustrating a portion of a pickup apparatus 200 according to a first modification of the embodiment.

In the pickup apparatus 100, the suction-holder 21 is linked to the presser 22 and the arm 24 via the elastic member 23. In the pickup apparatus 200 illustrated in FIGS. 5A to 5C, the presser 22 is linked to the arm 24 via an elastic member 25. More specifically, the presser 22 is slidable in the vertical direction with respect to the arm 24. The elastic member 25 is provided between the presser 22 and the arm 24.

As illustrated in FIG. 5A, the lower surface of the presser is positioned lower than the lower surface of the suction-holder 21 in the state in which the suction-holder 21 and the presser 22 do not contact the semiconductor chips 1. When the suction-holder 21 and the presser 22 contact the upper surfaces of the semiconductor chips 1 as illustrated in FIG. 5B, the elastic member 25 is compressed; and the lower surface of the presser 22 and the lower surface of the suction-holder 21 have the same position.

From this state, when the semiconductor chip 1a is lifted by the lifter 11 as illustrated in FIG. 5C, the suction-holder 21 and the arm 24 move upward accordingly. At this time, the elastic member 25 is still in the compressive state; and the presser 22 presses the upper surface of the semiconductor chip 1b due to the elastic force of the elastic member 25.

According to the modification, due to the elastic force of the elastic member 25, the suction-holder 21 can be moved upward with respect to the presser 22 while the semiconductor chip 1b is pressed by the presser 22. In the structure according to the modification as well, similarly to the structure illustrated in FIGS. 3A to 3D, the suction-holder 21 can be moved upward with respect to the presser 22 in a simple structure.

### Second Modification

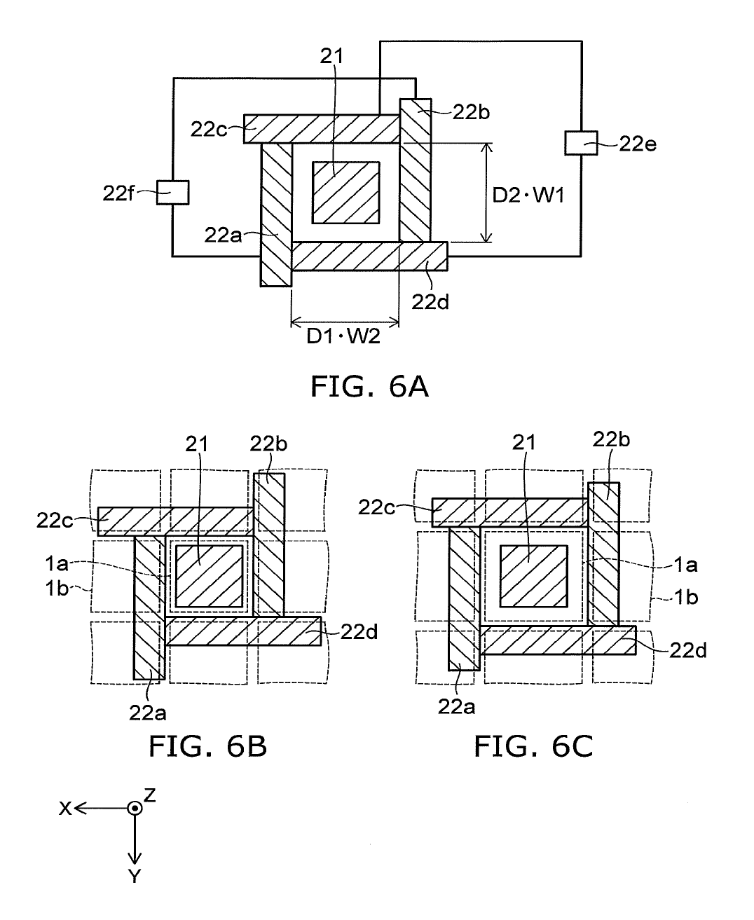

FIG. 6A to FIG. 6C are plan views illustrating a portion of a pickup apparatus 300 according to a second modification of the embodiment.

The suction-holder 21 and the presser 22 of the pickup head 20 are illustrated in FIG. 6A to FIG. 6C.

In the pickup apparatus 300 as illustrated in FIG. 6A, the presser 22 includes a first pressing member 22a, a second pressing member 22b, a third pressing member 22c, a fourth pressing member 22d, a first driver 22e, and a second driver 22f.

The first pressing member 22a and the second pressing member 22b are separated from each other in the X-axis direction (a first direction) along the upper surface of the sheet 2. The third pressing member 22c and the fourth pressing member 22d are separated from each other in the Y-axis direction (a second direction) perpendicular to the X-axis direction along the upper surface of the sheet 2.

The suction-holder 21 is positioned between the first pressing member 22a and the second pressing member 22b in the X-axis direction and is positioned between the third pressing member 22c and the fourth pressing member 22d in the Y-axis direction.

The first driver 22e drives the first pressing member 22a and the second pressing member 22b synchronously and changes a distance D1 between the pressing members in the X-axis direction. The first driver 22e can change an overlap width W1 in the X-axis direction between the first pressing member 22a and the second pressing member 22b. For example, the first driver 22e drives the first pressing member 22a and the second pressing member 22b to increase the overlap width W1 as the distance D1 lengthens.

Similarly, the second driver 22f drives the third pressing member 22c and the fourth pressing member 22d synchronously and changes a distance D2 between the pressing members in the Y-axis direction. The second driver 22f also can change an overlap width W2 in the Y-axis direction between the third pressing member 22c and the fourth pressing member 22d. For example, the second driver 22f drives the third pressing member 22c and the fourth pressing member 22d to increase the overlap width W2 as the distance D2 lengthens.

According to the pickup apparatus 300 according to the modification as illustrated in FIG. 6B and FIG. 6C, it is possible to modify the presser 22 according to the size of the semiconductor chip 1. According to the lengths in the X-axis direction and the Y-axis direction of the semiconductor chip 1, the distance between the first pressing member 22a and the second pressing member 22b and the distance between the third pressing member 22c and the fourth pressing member 22d can be changed. Thereby, it is possible to press the semiconductor chip 1b adjacent to the pickup object regardless of the size of the semiconductor chip 1.

By changing the overlap widths W1 and W2 according to the distances D1 and D2, the first to fourth pressing members 22a to 22d can be moved without widening the gaps between these pressing members as illustrated in FIG. 6B and FIG. 6C. Therefore, the semiconductor chips 1 can be pressed more reliably even in the case where the presser 22 is modified according to the size of the semiconductor chip 1.

In the example described above, the first pressing member 22a and the second pressing member 22b are driven by the first driver 22e; and the third pressing member 22c and the fourth pressing member 22d are driven by the second driver 22f. The pickup apparatus according to the modification is not limited thereto.

For example, four drivers may be provided to be able to drive the first to fourth pressing members 22a to 22d independently.

Either the set of the first pressing member 22a and the second pressing member 22b or the set of the third pressing member 22c and the fourth pressing member 22d may be provided in the presser 22. The dimension of the presser 22 in one of the X-axis direction or the Y-axis direction can be modified to match the size of the semiconductor chip 1.

Although several embodiments of the invention are illustrated hereinabove, these embodiments are presented as examples and are not intended to limit the scope of the invention. These novel embodiments may be implemented in other various forms; and various omissions, substitutions, modifications, etc., can be performed without departing from the spirit of the invention. These embodiments and their modifications are within the scope and spirit of the invention and are included in the invention described in the claims and their equivalents. The embodiments described above can be implemented in combination with each other.

What is claimed is:

1. A pickup apparatus picking up one of a plurality of semiconductor chips from a sheet, the plurality of semiconductor chips being adhered to an upper surface of the sheet, the pickup apparatus comprising:
a supporter configured to support another of the semiconductor chips from below, the other semiconductor chip being positioned adjacent to the one semiconductor chip;
a presser configured to press the other semiconductor chip from above, the other semiconductor chip being clamped between the presser and the supporter;
a suction-holder configured to be movable upward with respect to the presser, the suction-holder holding the one semiconductor chip from above; and
a lifter configured to lift the one semiconductor chip from below, the lifter urging the one semiconductor chip to peel from the sheet.

2. The apparatus according to claim 1, further comprising an arm linked to the suction-holder and the presser, the arm moving the suction-holder and the presser up and down,
the suction-holder being linked to the arm via an elastic member,
the suction-holder moving upward with respect to the presser by the elastic member compressing when the semiconductor chip to be picked up is lifted by the lifter in a state in which the suction-holder holds the semiconductor chip.

3. The apparatus according to claim 1, further comprising an arm linked to the suction-holder and the presser, the arm moving the suction-holder and the presser up and down,
the presser being linked to the arm via an elastic member,
the elastic member being compressed when the presser presses the adjacent semiconductor chip,
the presser pressing the adjacent semiconductor chip from above by an elastic force of the elastic member when the semiconductor chip to be picked up is lifted by the lifter as the arm and the suction-holder are moved upward with respect to the presser.

4. The apparatus according to claim 1, wherein the presser and the supporter clamp a plurality of the other semiconductor chips.

5. The apparatus according to claim 1, wherein the presser presses, from above, an end portion of the other semiconductor chip on the one semiconductor chip side.

6. The apparatus according to claim 1, wherein a length of the lifter in a first direction is shorter than a length of the suction-holder in the first direction, the first direction being along the upper surface of the sheet.

7. The apparatus according to claim 1, wherein a length of the suction-holder in a first direction is shorter than a length of the one semiconductor chip in the first direction, the first direction being along the upper surface of the sheet.

8. The apparatus according to claim 1, wherein the suction-holder holds the one semiconductor chip by suctioning an upper surface of the one semiconductor chip.

9. The apparatus according to claim 1, wherein the supporter holds the sheet by suctioning a lower surface of the sheet.

10. The apparatus according to claim 1, wherein
the presser includes:
a first pressing member;
a second pressing member separated from the first pressing member in a first direction, the first direction being along the upper surface of the sheet; and
a first driver driving the first pressing member and the second pressing member, the first driver changing a distance in the first direction between the first pressing member and the second pressing member,
the suction-holder being provided between the first pressing member and the second pressing member in the first direction.

11. The apparatus according to claim 4, wherein
the presser further includes:
a third pressing member;
a fourth pressing member separated from the third pressing member in a second direction, the second direction being along the upper surface of the sheet and perpendicular to the first direction; and
a second driver driving the third pressing member and the fourth pressing member, the second driver changing a distance in the second direction between the third pressing member and the fourth pressing member,
the suction-holder being provided between the third pressing member and the fourth pressing member in the second direction.
